(19) United States
(12) Patent Application Publication
(10) Pub. No.: US 2026/0186046 A1
(43) Pub. Date: Jul. 2, 2026

(54) SEMICONDUCTOR TESTING DEVICE

(71) Applicant: KABUSHIKI KAISHA NIHON MICRONICS, Tokyo (JP)

(72) Inventors: Hideki IKEUCHI, Musashino-shi (JP); Furawa ODAGIRI, Musashino-shi (JP); Shoujirou YAHATA, Musashino-shi (JP)

(73) Assignee: KABUSHIKI KAISHA NIHON MICRONICS, Tokyo (JP)

(21) Appl. No.: 19/413,141

(22) Filed: Dec. 9, 2025

(30) Foreign Application Priority Data
Dec. 26, 2024 (JP) 2024-230401

(51) Int. Cl. G01R 31/28

(52) U.S. Cl. CPC G01R 31/2868; G01R 31/2867

(57) ABSTRACT

A tester includes a performance board unit on which a probe card is mounted, a plurality of board units electrically connected to the probe card via the performance board unit, a plurality of power supply units supplying power to the plurality of board units, and a main body unit, on which the performance board unit is mounted, including a first accommodating portion that accommodates the plurality of board units and a second accommodating portion that accommodates the plurality of power supply units, in which the plurality of power supply units are detachably attached to the second accommodating portion, and the main body unit includes a bus bar electrically connected to the plurality of power supply units in an attachment/detachment direction (Y-axis direction) of the plurality of power supply units with respect to the second accommodating portion.

### BACKGROUND OF THE INVENTION

### Field of the Invention

The present invention relates to a semiconductor testing device.

Priority is claimed on Japanese Patent Application No. 2024-230401, filed on Dec. 26, 2024, the content of which is incorporated herein by reference.

### Description of Related Art

Patent Document 1 (Japanese Unexamined Patent Application, First Publication No. 2004-172551) discloses a wafer test system that performs electrical inspection of a plurality of semiconductor chips (dies) formed on a semiconductor wafer.

This wafer test system includes a prober that brings a probe into contact with an electrode of a semiconductor chip formed on a wafer, and a tester that has a terminal electrically connected to the probe, operates the semiconductor chip via the terminal, and inspects electrical characteristics of the semiconductor chip by detecting an output signal thereof.

This tester (semiconductor testing device) includes a tester main body, a test head, and a cable connecting the tester main body and the test head. The test head includes a probe card (device under test) and a performance board (signal transmission unit) electrically connected to a terminal of the probe card. The tester main body includes a board unit that exchanges signals with the test head via the cable, and a power supply unit that supplies power to the board unit.

### SUMMARY OF THE INVENTION

The tester described above has a configuration in which the tester main body and the test head are connected via the cable, but in recent years, there has been a demand for a compact tester in which the tester main body and the test head (performance board) are integrated. Such a tester houses board units and power supply units in a single housing, and when the number of board units is increased or decreased or replaced according to specifications of the semiconductor chips, it has been necessary to also increase or decrease the capacity of the power supply units according to the amount of power supplied to the respective board units.

Therefore, the inventors of the present application have considered a configuration in which a plurality of power supply units are made attachable to and detachable from the tester main body (main body unit). However, when the power supply units are connected to the tester main body by cables, as many cable connection operations as the number of power supply units are required. Also, since the cables become thicker according to the amount of power supplied to the board units, a space is required for routing or bundling the cables, which constrains an internal space of the tester main body, and causes a problem that the tester main body increases in size.

The present invention has been made in view of the above-described problems, and an objective thereof is to provide a compact semiconductor testing device in which attachment and detachment work of a plurality of power supply units is facilitated.

A semiconductor testing device according to one aspect of the present invention includes a signal transmission unit on which a device under test for testing a semiconductor circuit is mounted, a plurality of board units electrically connected to the device under test via the signal transmission unit, a plurality of power supply units supplying power to the plurality of board units, and a main body unit, on which the signal transmission unit is mounted, including a first accommodating portion which accommodates the plurality of board units and a second accommodating portion which accommodates the plurality of power supply units, in which the plurality of power supply units are detachably attached to the second accommodating portion, and the main body unit includes a bus bar electrically connected to the plurality of power supply units in an attachment/detachment direction of the plurality of power supply units with respect to the second accommodating portion.

According to the above-described aspect of the present invention, it is possible to provide a compact semiconductor testing device in which attachment and detachment work of a plurality of power supply units is facilitated.

### BRIEF DESCRIPTION OF THE DRAWINGS

FIG. 1 is a schematic view of an inspection system including a tester according to one embodiment.

FIG. 2 is a perspective view of the tester according to one embodiment.

FIG. 3 is an exploded perspective view of the tester according to one embodiment.

FIG. 4 is a perspective view of the tester according to one embodiment with a side cover removed.

FIG. 5 is a schematic view of the tester according to one embodiment from an attachment/detachment direction of a power supply unit.

FIG. 6 is a perspective view illustrating a connection state between a bus bar and the power supply unit according to one embodiment.

FIG. 7 is a perspective view of the power supply unit according to one embodiment.

FIG. 8 is a view along the arrow VIII illustrated in FIG. 5.

### DETAILED DESCRIPTION OF THE INVENTION

Hereinafter, an embodiment of the present invention will be described on the basis of the drawings.

The embodiment described below is intended to exemplify apparatuses and methods for embodying the technical ideas of this invention, and the embodiment of the invention is not intended to limit materials, shapes, structures, arrangements, and the like of the components to those described below.

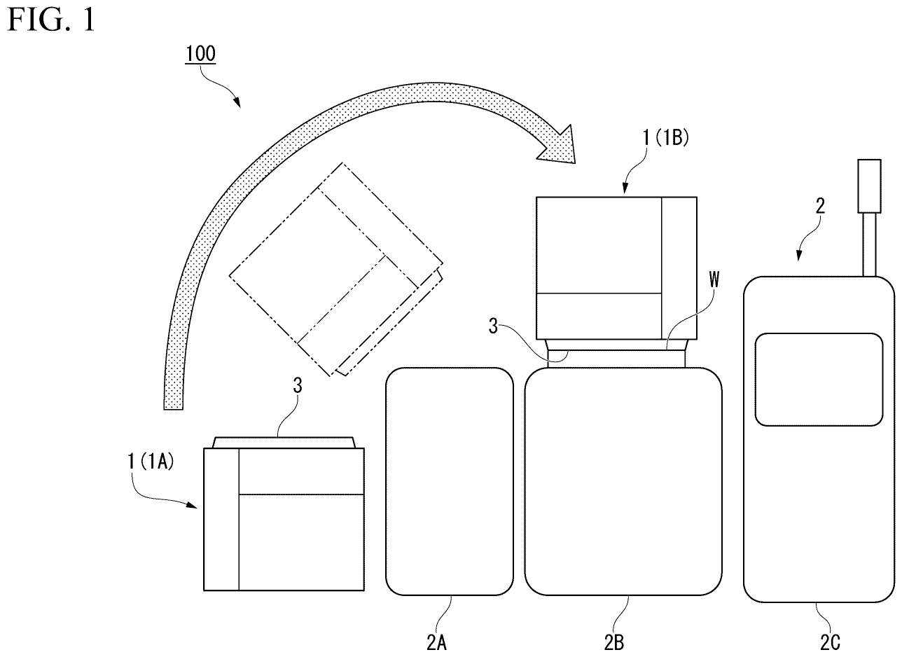

FIG. 1 is a schematic view of an inspection system 100 including a tester 1 according to one embodiment.

The inspection system 100 illustrated in FIG. 1 includes the tester 1 (semiconductor testing device) and a prober 2. The inspection system 100 inspects electrical characteristics of respective semiconductor circuits before a plurality of semiconductor circuits formed on a wafer W are individually diced into chips.

A probe card 3 (device under test) is mounted on the tester 1. The probe card 3 includes a plurality of probes (test needles). The prober 2 brings the plurality of probes provided on the probe card 3 into contact with pads of the plurality of semiconductor circuits formed on the wafer W. The prober 2 includes a tester moving device 2A, a stage device 2B, and a wafer transfer device 2C.

The tester moving device 2A includes a moving mechanism (not illustrated) and moves the tester 1 between a standby position 1A and an inspection position 1B. The stage device 2B supports the wafer W and aligns the tester 1 positioned at the inspection position 1B with the wafer W. The stage device 2B is movable in a planar direction along a horizontal plane and in a vertical direction perpendicular to the horizontal plane, and is also rotatable in a θ direction around a vertical axis. The wafer transfer device 2C transfers the wafer W onto the stage device 2B.

When the inspection is performed, the stage device 2B moves the wafer W and brings pads of the plurality of semiconductor circuits formed on the wafer W into contact with distal end parts of the plurality of probes provided on the tester 1 positioned at the inspection position 1B. In this state, the tester 1 inputs test signals simultaneously to the respective semiconductor circuits via the plurality of probes, and inspects the semiconductor circuits by receiving output signals from the respective semiconductor circuits.

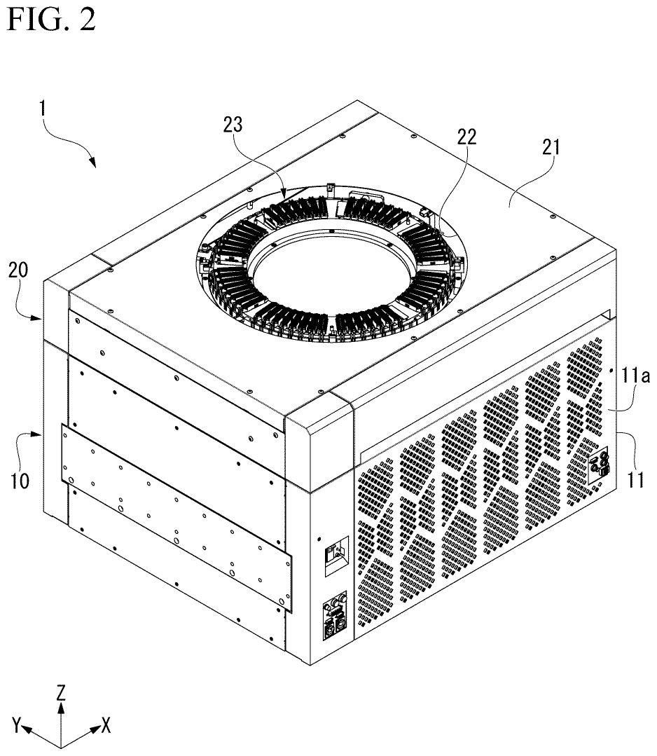

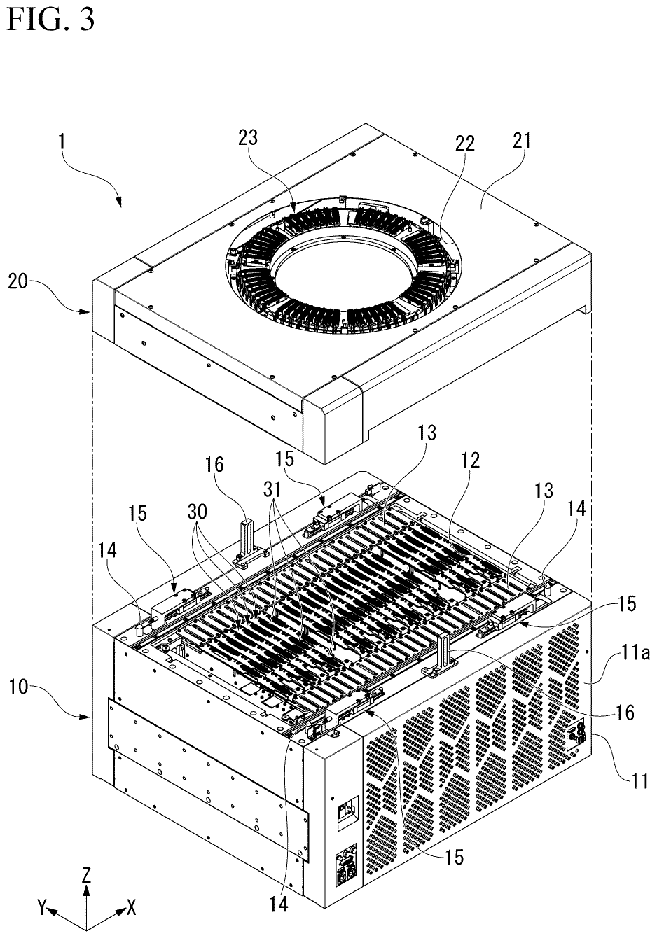

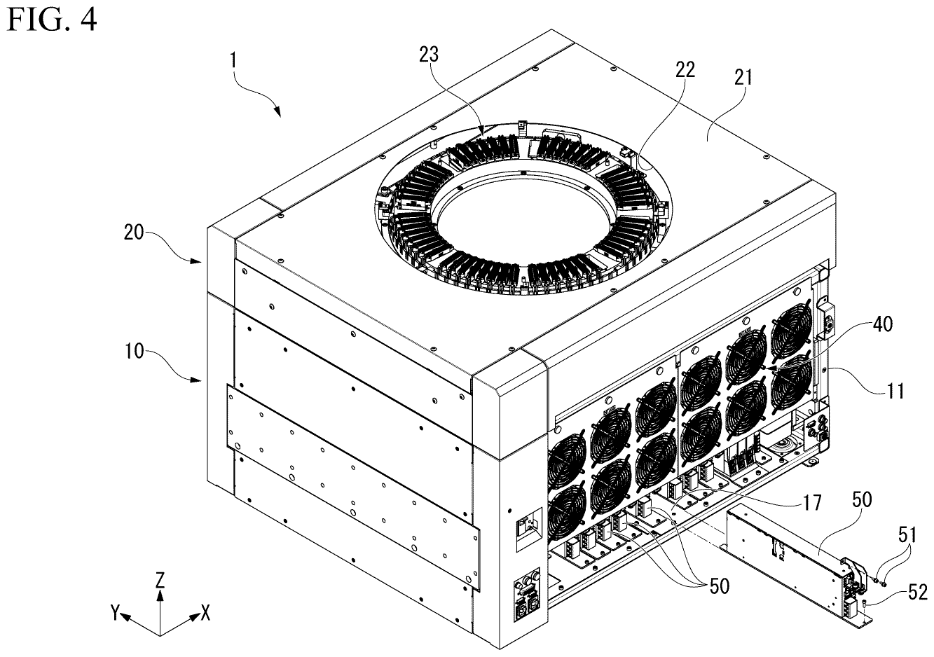

FIG. 2 is a perspective view of the tester 1 according to one embodiment. FIG. 3 is an exploded perspective view of the tester 1 according to one embodiment. FIG. 4 is a perspective view of the tester 1 according to one embodiment with a side cover 11a removed.

As illustrated in FIG. 2, the tester 1 includes a main body unit 10 and a performance board unit 20 (signal transmission unit). The tester 1 is formed in a rectangular box shape as a whole. The main body unit 10 accommodates a plurality of board units 30 (see FIG. 3) and a plurality of power supply units 50 (see FIG. 4) that supply power to the plurality of board units 30.

Further, in the following description, an XYZ orthogonal coordinate system is set, and positional relationships of respective members may be described with reference to the XYZ orthogonal coordinate system. An X-axis direction is a first linear direction along a horizontal plane, a Y-axis direction is a second linear direction perpendicular to the first linear direction on the horizontal plane, and a Z-axis direction is a vertical direction. Further, in the present embodiment, for convenience of explanation, a side closer to the main body unit 10 is described as being disposed on a lower side (−Z side), and a side closer to the performance board unit 20 is described as being disposed on an upper side (+Z side), but this positional relationship can be changed depending on an orientation or posture of the tester 1.

As illustrated in FIG. 2, the performance board unit 20 includes a unit cover 21 in which an opening 22 is formed. The opening 22 is formed at a center of an upper surface of the unit cover 21. The opening 22 is formed in a circular shape in a plan view from the Z-axis direction. From the opening 22, a device mounting portion 23 on which the probe card 3 (see FIG. 1) can be mounted is exposed. The performance board unit 20 is detachably attached to an upper part of the main body unit 10.

As illustrated in FIG. 3, the main body unit 10 includes a rectangular box-shaped housing 11 that is open on an upper side. Inside the housing 11, a first accommodating portion 12, which is open on an upper side and accommodates the plurality of board units 30, is formed. The plurality of board units 30 are accommodated in the first accommodating portion 12 with gaps between them in the X-axis direction. The plurality of board units 30 generate test signals to be input to the plurality of semiconductor circuits formed on the wafer W, and receive and inspect output signals from the respective semiconductor circuits. The plurality of board units 30 can be increased or decreased in number, or replaced, in accordance with specifications of the semiconductor circuits formed on the wafer W.

A plurality of (two or three) first connectors 31 are provided on an upper part of each of the plurality of board units 30. The plurality of first connectors 31 are connected to a lower surface of the performance board unit 20. A board holder 13 that protrudes horizontally toward the first accommodating portion 12 and restricts upward removal of the plurality of board units 30 is detachably attached to an upper end opening edge of the housing 11.

Also, a positioning pin 14 for positioning the performance board unit 20, a clamp device 15 for clamping the performance board unit 20, and a lock bracket 16 for locking the performance board unit 20 are provided at the upper end opening edge of the housing 11. The positioning pin 14 is provided at positions corresponding to three of four corner portions of the housing 11 in a plan view. Thereby, the performance board unit 20 can be prevented from being attached to the main body unit 10 in an incorrect orientation.

A total of four clamp devices 15 are provided, two on each of two sides of the upper end opening edge of the housing 11 extending in the X-axis direction. Of the four clamp devices 15, three cause clamp pins to advance and retract in the X-axis direction toward the positioning pins 14. The remaining one of the clamp devices 15 causes a clamp pin to advance and retract in the X-axis direction toward a corner portion of the housing 11 in which no positioning pin 14 is provided. The clamp device 15 is electrically driven and can be switched between a clamped state and an unclamped state with the performance board unit 20. A pair of lock brackets 16, each having an elongated hole extending in the Z-axis direction, are provided with the first accommodating portion 12 interposed therebetween in the Y-axis direction.

The performance board unit 20 includes a performance board (not illustrated) on which the device mounting portion 23 is mounted. The performance board is interposed between the probe card 3 (see FIG. 1) and the plurality of board units 30 (see FIG. 3), and transmits signals required for testing. Also, the performance board unit 20 includes a plurality of second connectors (not illustrated) that are connected to the plurality of first connectors 31, and a lock plunger (not illustrated) that can switch between an engaged state and a disengaged state with respect to the lock bracket 16.

A plurality of ventilation holes are formed in the side cover 11a of the housing 11. The side cover 11a is configured to be detachable from the housing 11 as illustrated in FIG. 4 and covers a fan unit 40 provided inside the housing 11. The fan unit 40 air-cools the plurality of board units 30 (see FIG. 3) accommodated in the first accommodating portion 12. In the housing 11, a second accommodating portion 17 that accommodates the plurality of power supply units 50 is formed below the fan unit 40 (first accommodating portion 12). The second accommodating portion 17 opens toward the −Y side.

The plurality of power supply units 50 are disposed in a row in the X-axis direction in the second accommodating portion 17. The plurality of power supply units 50 are detachably attached to the second accommodating portion 17 in the Y-axis direction. In the following description, the Y-axis direction may be referred to as an attachment/detachment direction of the power supply unit 50. Also, the +Y side may be referred to as a rear side in the attachment/detachment direction of the power supply unit 50, and the −Y side may be referred to as a front side in the attachment/detachment direction of the power supply unit 50. The plurality of power supply units 50 are detachably fixed to the main body unit 10 with bolts 51 and 52.

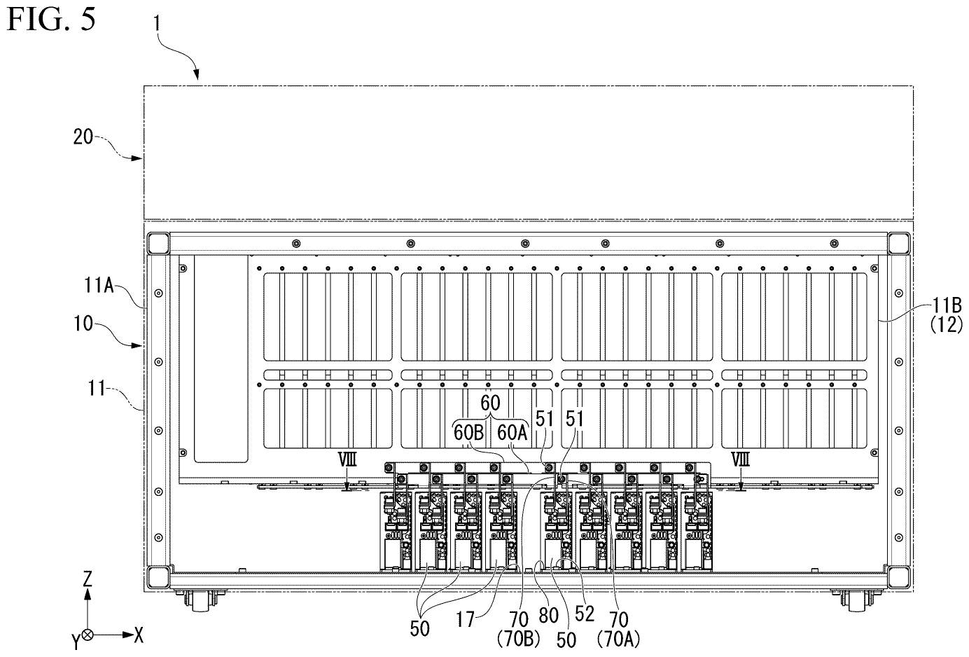

FIG. 5 is a schematic view of the tester 1 according to one embodiment from the attachment/detachment direction of the power supply unit 50. Further, in FIG. 5, for improved visibility, only components related to attachment and detachment of the power supply unit 50 are illustrated.

As illustrated in FIG. 5, a frame portion 11A and a cage portion 11B disposed inside the frame portion 11A are provided inside the main body unit 10. The frame portion 11A has a substantially rectangular parallelepiped frame shape.

The cage portion 11B is attached to the inside of an upper end part of the frame portion 11A. The cage portion 11B has a cage structure of a substantially angular C shape or a substantially U shape that is open upward. The first accommodating portion 12 described above is formed inside the cage portion 11B. The above-described fan unit 40 (see FIG. 4) is attached to a surface of the cage portion 11B facing outward in the Y-axis direction. The second accommodating portion 17 is formed inside the frame portion 11A and below the cage portion 11B.

The main body unit 10 includes a bus bar 60 that is electrically connected to the plurality of power supply units 50 in the attachment/detachment direction (Y-axis direction) of the plurality of power supply units 50. The bus bar 60 is formed of a conductive metal material and is electrically connected to a backplane board (not illustrated) provided at a bottom part of the cage portion 11B. Also, the backplane board is electrically connected to the plurality of board units 30 accommodated in the first accommodating portion 12. Thereby, power can be supplied from the plurality of power supply units 50 to the plurality of board units 30. The bus bar 60 includes a first bus bar 60A connected to an anode side of the plurality of power supply units 50, and a second bus bar 60B connected to a cathode side of the plurality of power supply units 50.

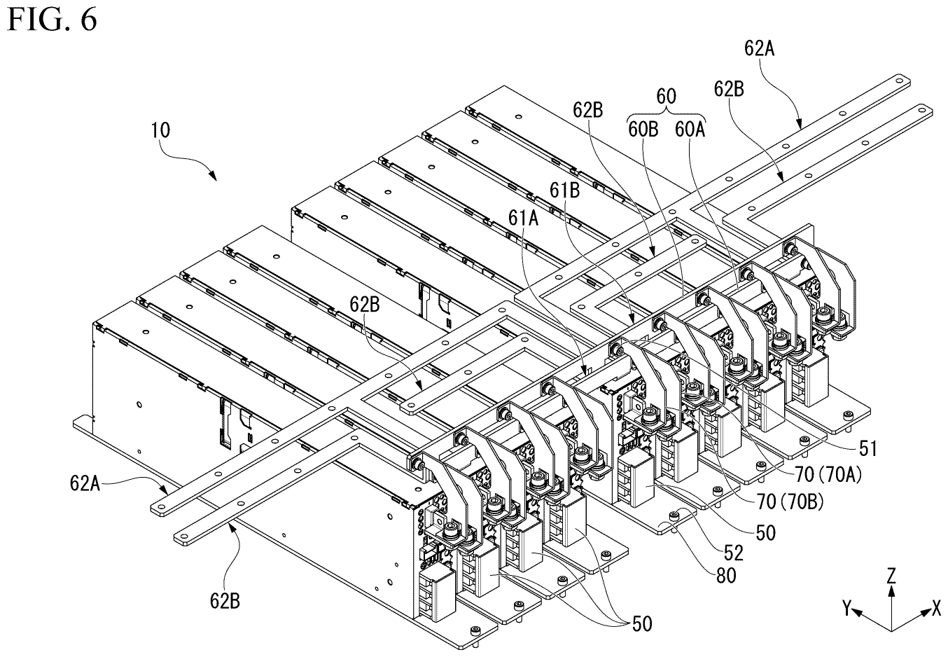

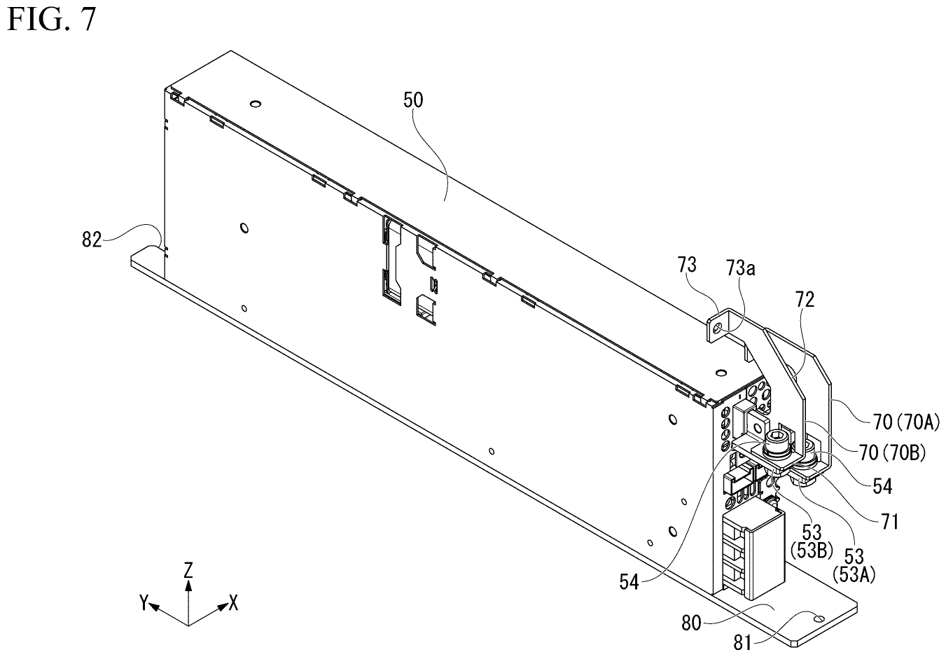

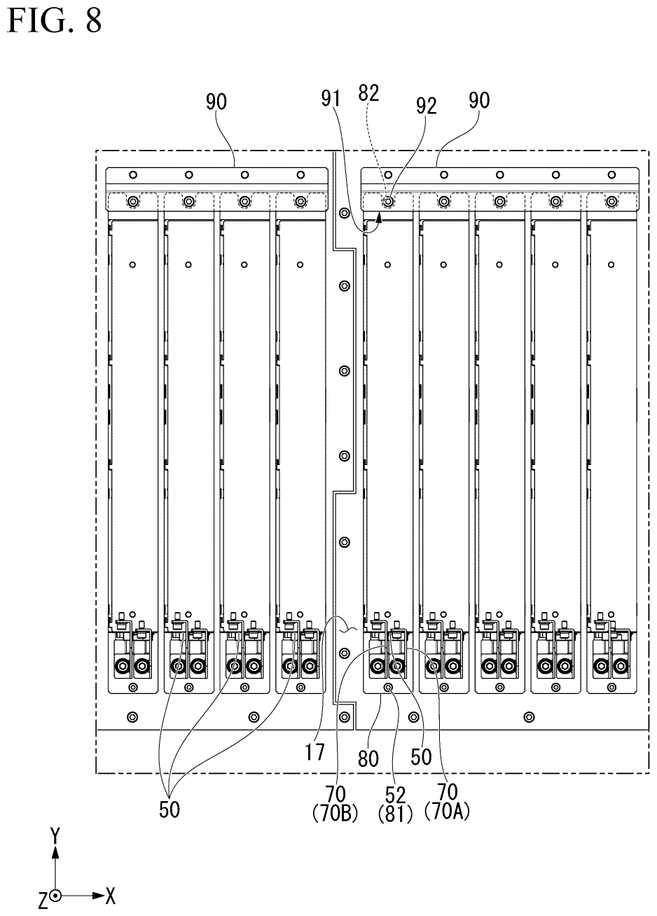

FIG. 6 is a perspective view illustrating a connection state between the bus bar 60 and the power supply unit 50 according to one embodiment. FIG. 7 is a perspective view of the power supply unit 50 according to one embodiment. FIG. 8 is a view along the arrow VIII illustrated in FIG. 5.

As illustrated in FIG. 6, the first bus bar 60A includes a first power supply-side connection portion 61A and a first board-side connection portion 62A. Also, the second bus bar 60B includes a second power supply-side connection portion 61B and a second board-side connection portion 62B.

The first power supply-side connection portion 61A has a rod shape that extends linearly in the X-axis direction. The first power supply-side connection portion 61A is attached to a lower end part of a surface of the cage portion 11B facing the −Y side illustrated in FIG. 5. The first power supply-side connection portion 61A is mechanically and electrically connected to a bus bar connection terminal 70 of the power supply unit 50 via the bolt 51 in the Y-axis direction. Further, the first power supply-side connection portion 61A is electrically insulated from the cage portion 11B.

The first board-side connection portion 62A is provided to be connected to the first power supply-side connection portion 61A and has a branch shape extending along an X-Y plane. The first board-side connection portion 62A is attached to the bottom part of the cage portion 11B illustrated in FIG. 5. Specifically, the first board-side connection portion 62A is mechanically and electrically connected to the backplane board (not illustrated) provided at the bottom part of the cage portion 11B via a bolt (not illustrated). Further, the first board-side connection portion 62A is electrically insulated from the cage portion 11B.

The second power supply-side connection portion 61B has a rod shape that extends linearly in the X-axis direction. The second power supply-side connection portion 61B is attached to an upper side of the first power supply-side connection portion 61A at a lower end part of the surface of the cage portion 11B facing the −Y side illustrated in FIG. 5, and extends parallel to the first power supply-side connection portion 61A. The second power supply-side connection portion 61B is mechanically and electrically connected to the bus bar connection terminal 70 of the power supply unit 50 via the bolt 51 in the Y-axis direction. Further, the second power supply-side connection portion 61B is electrically insulated from the cage portion 11B.

The second board-side connection portion 62B is provided to be connected to the second power supply-side connection portion 61B, and has a branch shape extending along the X-Y plane with a gap between itself and the first board-side connection portion 62A. The second board-side connection portion 62B is attached to the bottom part of the cage portion 11B illustrated in FIG. 5. Specifically, the second board-side connection portion 62B is mechanically and electrically connected to the backplane board (not illustrated) provided at the bottom part of the cage portion 11B via a bolt (not illustrated). Further, the second board-side connection portion 62B is electrically insulated from the cage portion 11B.

As illustrated in FIG. 7, the power supply unit 50 has a substantially rectangular parallelepiped shape extending in the Y-axis direction. A power supply terminal 53 is provided on a surface of the power supply unit 50 facing the −Y side. The bus bar connection terminal 70 is mechanically and electrically connected to the power supply terminal 53 via a bolt 54. The power supply unit 50 includes, as the power supply terminal 53, a first power supply terminal 53A on the anode side and a second power supply terminal 53B on the cathode side. Also, the power supply unit 50 also includes, as the bus bar connection terminal 70, a first bus bar connection terminal 70A connected to the first power supply terminal 53A and a second bus bar connection terminal 70B connected to the second power supply terminal 53B.

The bus bar connection terminal 70 extends upward from the power supply terminal 53 beyond an upper surface of the power supply unit 50 and has a shape that is bent toward the rear side (+Y side) in the attachment/detachment direction of the power supply unit 50. Specifically, the bus bar connection terminal 70 includes an electrode-side fixing portion 71, a bent portion 72, and a bus bar-side fixing portion 73. The electrode-side fixing portion 71 is formed in a plate shape along the X-Y plane, and is fixed to the power supply terminal 53 in the Z-axis direction via the bolt 54.

The bent portion 72 is a portion bent at a right angle to the +Z side from an end edge on the +X side of the electrode-side fixing portion 71 and is formed in a plate shape along a Y-Z plane. The bent portion 72 includes a first portion linearly extending vertically upward from an end edge on the +X side of the electrode-side fixing portion 71, a second portion extending obliquely at an angle of 45 degrees with respect to the horizontal plane (X-Y plane) from an end part of the first portion toward the rear side (+Y side) in the attachment/detachment direction, and a third portion linearly extending horizontally from an end part of the second portion toward the rear side (+Y side) in the attachment/detachment direction.

The bus bar-side fixing portion 73 is a portion bent at a right angle from an end part of the third portion of the bent portion 72 to the −X side, and is formed in a plate shape along an X-Z plane. A through hole 73a penetrating in the Y-axis direction is formed in the bus bar-side fixing portion 73. The bolt 51 illustrated in FIG. 6 is inserted into the through hole 73a. The bolt 51 mechanically and electrically connects the bus bar connection terminal 70 and the bus bar 60 in the Y-axis direction.

As illustrated in FIG. 7, the power supply unit 50 is mounted on a slide plate 80. The slide plate 80 is fixed to a bottom surface of the power supply unit 50 via a countersunk screw or the like. The slide plate 80 is formed in a plate shape that is longer than the power supply unit 50 on both sides in the Y-axis direction. A fixing hole 81 penetrating in the Z-axis direction is formed at an end part on the −Y side of the slide plate 80. The bolt 52 illustrated in FIG. 5 is inserted into the fixing hole 81. The bolt 52 mechanically fixes the slide plate 80 and the main body unit 10 in the Z-axis direction.

As illustrated in FIG. 8, a positioning recessed portion 82 is provided at an end part on the +Y side of the slide plate 80. The positioning recessed portion 82 is a cutout formed in a semicircular or substantially U shape in a plan view from the Z-axis direction. A fixing piece 90 is provided on the rear side (+Y side) of the second accommodating portion 17. The fixing piece 90 has a crank-shaped bent form, and forms a gap 91 into which an end part on the +Y side of the slide plate 80 can be inserted in the Y-axis direction.

A positioning protruding portion 92 with which the positioning recessed portion 82 engages is provided in the second accommodating portion 17. The positioning protruding portion 92 is provided in a columnar shape within the gap 91 of the fixing piece 90 and engages with the positioning recessed portion 82 of the slide plate 80 inserted into the gap 91. The positioning protruding portion 92 is configured to include, for example, a bolt penetrating the gap 91 of the fixing piece 90 in the Z-axis direction and fixed to a bottom surface of the second accommodating portion 17, and a cylindrical spacer disposed in the gap 91 and through which the bolt passes.

When the power supply unit 50 having the above-described configuration is attached to the main body unit 10, first, the side cover 11a is removed from the main body unit 10 as illustrated in FIG. 4. Next, the power supply unit 50 is inserted into the empty portion of the second accommodating portion 17 in the Y-axis direction. When the power supply unit 50 is inserted in the Y-axis direction, as illustrated in FIG. 8, an end part on the +Y side of the slide plate 80 on which the power supply unit 50 is mounted is inserted into the gap 91 of the fixing piece 90, and the positioning recessed portion 82 engages with the positioning protruding portion 92. In this state, as illustrated in FIGS. 5 and 6, the bus bar 60 and the bus bar connection terminal 70 are aligned in position and fixed in the Y-axis direction with the bolt 51. Then, the end part on the −Y side of the slide plate 80 is fixed to the bottom surface of the second accommodating portion 17 in the Z-axis direction with the bolt 52. Finally, the removed side cover 11a is attached to the main body unit 10.

In this manner, the power supply unit 50 can be attached to the main body unit 10. Further, when the power supply unit 50 is removed from the main body unit 10, the above-described procedure is performed in reverse.

As described above, in the present embodiment, since the power supply unit 50 and the bus bar 60 are electrically connected in the attachment/detachment direction (Y-axis direction), connection work such as cabling is unnecessary, and connection work is facilitated. Also, since the bus bar 60 only needs to have a width and thickness according to an amount of power supplied to the respective board unit 30, it can be disposed in a space-saving manner inside the main body unit 10. Thereby, an overall height of the second accommodating portion 17 can be prevented from increasing, and the main body unit 10 can be made more compact.

As described above, the tester 1 according to the present embodiment includes the performance board unit 20 on which the probe card 3 for testing a semiconductor circuit is mounted, the plurality of board units 30 electrically connected to the probe card 3 via the performance board unit 20, the plurality of power supply units 50 supplying power to the plurality of board units 30, and the main body unit 10, on which the performance board unit 20 is mounted, including the first accommodating portion 12 that accommodates the plurality of board units 30 and the second accommodating portion 17 that accommodates the plurality of power supply units 50, in which the plurality of power supply units 50 are detachably attached to the second accommodating portion 17, and the main body unit 10 includes the bus bar 60 electrically connected to the plurality of power supply units 50 in the attachment/detachment direction (Y-axis direction) of the plurality of power supply units 50 with respect to the second accommodating portion 17. According to this configuration, it is possible to obtain the compact tester 1 in which attachment and detachment work of the plurality of power supply units is facilitated.

Also, in the present embodiment, the plurality of power supply units 50 each include the bus bar connection terminal 70 that is fixed to the bus bar 60 via the bolt 51 in the attachment/detachment direction. According to this configuration, since the attachment/detachment direction of the power supply unit 50 coincides with the connection direction of the bus bar connection terminal 70 with respect to the bus bar 60, a fixing operation with the bolt 51 is facilitated.

Also, in the present embodiment, the bus bar connection terminal 70 is provided on the front side (−Y side) in the attachment/detachment direction in each unit of the plurality of power supply units 50. According to this configuration, since the fixing operation of the bolt 51 can be performed in an open space on the front side (−Y side) of the second accommodating portion 17, the operation is easier than performing the fixing operation of the bolt 51 in a closed space on the rear side (+Y side) of the second accommodating portion 17.

Also, in the present embodiment, in each unit of the plurality of power supply units 50, the bus bar connection terminal 70 extends from the power supply terminal 53 provided on a surface facing the front side (−Y side) in the attachment/detachment direction toward above each of the power supply units 50, and bends toward the rear side (+Y side) in the attachment/detachment direction. According to this configuration, it is easier to bring the bus bar connection terminal 70 into contact with the bus bar 60 in the attachment/detachment direction (Y-axis direction), and since the bus bar connection terminal 70 extends upward above the power supply unit 50 without extending to the left or right, the plurality of power supply units 50 can be disposed at high density in the X-axis direction as illustrated in FIG. 5.

Also, in the present embodiment, each unit of the plurality of power supply units 50 is mounted on the slide plate 80 that is slidable in the attachment/detachment direction in the second accommodating portion 17. According to this configuration, insertion of the power supply unit 50 into the second accommodating portion 17 is facilitated.

Also, in the present embodiment, the positioning recessed portion 82 is provided on the rear side (+Y side) of the slide plate 80 in the attachment/detachment direction, and the positioning protruding portion 92 with which the positioning recessed portion 82 engages is provided on the rear side (+Y side) of the second accommodating portion 17 in the attachment/detachment direction. According to this configuration, since the power supply unit 50 can be positioned with respect to the second accommodating portion 17 at the same time as the power supply unit 50 is inserted, the bus bar connection terminal 70 can be more easily fixed to the bus bar 60.

Also, in the present embodiment, the fixing hole 81 that can be fixed to the main body unit 10 via the bolt 52 is provided on the front side (−Y side) of the slide plate 80 in the attachment/detachment direction. According to this configuration, since the connection state of the power supply unit 50 can be maintained, for example, even when the tester 1 is used upside down as illustrated in FIG. 1, the connection state of the power supply unit 50 is maintained and stable power can be supplied to each board unit 30.

While preferred embodiments of the present invention have been described and illustrated above, it should be understood that these are exemplary of the present invention and are not to be considered as limiting. Additions, omissions, substitutions, and other modifications can be made without departing from the scope of the present invention. Accordingly, the present invention is not to be considered as being limited by the foregoing description and is only limited by the scope of the claims.

For example, in the above-described embodiment, the probe card 3 has been exemplified as the device under test, but the present invention is not limited to this configuration. For example, the semiconductor testing device described above may also be used in a handler that performs inspection by placing semiconductor circuits on a test socket after the semiconductor circuits are diced into chips from the wafer W and then packaged. In this case, the test socket may be the device under test.

In addition, the components in the above-described embodiments can be appropriately replaced with well-known components within a range not departing from the spirit of the present invention, and the embodiments and modified examples described above may be appropriately combined.

What is claimed is:

1. A semiconductor testing device comprising:
a signal transmission unit on which a device under test for testing a semiconductor circuit is mounted;
a plurality of board units electrically connected to the device under test via the signal transmission unit;
a plurality of power supply units supplying power to the plurality of board units; and
a main body unit, on which the signal transmission unit is mounted, including a first accommodating portion which accommodates the plurality of board units and a second accommodating portion which accommodates the plurality of power supply units, wherein
the plurality of power supply units are detachably attached to the second accommodating portion, and
the main body unit includes a bus bar electrically connected to the plurality of power supply units in an attachment/detachment direction of the plurality of power supply units with respect to the second accommodating portion.

2. The semiconductor testing device according to claim 1, wherein the plurality of power supply units each include a bus bar connection terminal fixed to the bus bar via a bolt in the attachment/detachment direction.

3. The semiconductor testing device according to claim 2, wherein the bus bar connection terminal is provided on a front side in the attachment/detachment direction in each unit of the plurality of power supply units.

4. The semiconductor testing device according to claim 3, wherein
in each unit of the plurality of power supply units, the bus bar connection terminal extends from a power supply terminal provided on a surface facing the front side in the attachment/detachment direction toward above each of the power supply units, and bends toward a rear side in the attachment/detachment direction.

5. The semiconductor testing device according to claim 1, wherein each unit of the plurality of power supply units is mounted on a slide plate which is slidable in the attachment/detachment direction in the second accommodating portion.

6. The semiconductor testing device according to claim 5, wherein
a positioning recessed portion is provided on a rear side of the slide plate in the attachment/detachment direction, and
a positioning protruding portion with which the positioning recessed portion engages is provided on a rear side of the second accommodating portion in the attachment/detachment direction.

7. The semiconductor testing device according to claim 5, wherein a fixing hole for being fixed to the main body unit via a bolt is provided on a front side of the slide plate in the attachment/detachment direction.
